(19) United States
(12) Patent Application Publication
(10) Pub. No.: US 2026/0106447 A1
(43) Pub. Date: Apr. 16, 2026

(54) CURRENT RETURN CHANNEL AND METHOD FOR THE USE OF A RESIDUAL CURRENT DEVICE WITH A DIFFERENTIAL CURRENT SENSOR IN AN UNGROUNDED DC POWER SUPPLY SYSTEM

(71) Applicant: Bender GmbH & Co. KG, Gruenberg (DE)

(72) Inventors: Julian Reitz, Gruenberg (DE); Karl Schepp, Reiskirchen (DE)

(21) Appl. No.: 19/353,840

(22) Filed: Oct. 9, 2025

(30) Foreign Application Priority Data
Oct. 11, 2024 (DE) 10 2024 129 448.5

(51) Int. Cl. H02H 3/10; G01R 19/10; G01R 31/12; H02H 1/00; H02H 3/02

(52) U.S. Cl. CPC H02H 3/105; G01R 19/10; G01R 31/1272; H02H 1/0007; H02H 3/025

(57) ABSTRACT

The invention relates to a current return channel (20) and a method for the use of a residual current device (4) with a differential current sensor (8) in an ungrounded DC power supply system (2) in which the current return channel (20) is used. The current return channel (20) consists of an electronic circuit (22) which is coupled between each one of the active conductors (DC+, DC−) of the ungrounded power supply system (2) and ground (PE) via two terminals and is configured to be automatically activated temporarily when a low-resistance insulation fault (1) appears momentarily intermittently in order to form a fault circuit in which a current-limited fault current (I_{f}) flows, which triggers the residual current device (4).

### TECHNICAL FIELD

The invention relates to a current return channel and a method for the use of a residual current device with a differential current sensor (measuring current transformer) in an ungrounded DC power supply system having active conductors.

### BACKGROUND

The ungrounded DC power supply system and the residual current device installed in the ungrounded DC power supply system represent a prerequisite application environment for the invention and are not part of the invention.

When supplying electrical operating equipment, an ungrounded power supply system—also known as an isolated network (IT network)—is often used to meet increased requirements for operational, fire, and touch safety. Such networks are described in the standard DIN VDE 0100-410. The advantage of these networks is that the function of the electrical operating equipment is not impaired in the event of a first insulation fault (ground fault or body fault).

The operation of such a network generally requires the use of an insulation monitoring system to generate an alarm notification when a first fault occurs and to locate and eliminate the insulation fault as quickly as possible before a second fault causes the network to shut down. The requirements for suitable insulation monitoring devices (IMDs) are specified in the international standard IEC 61557-8.

Although the insulation monitoring device identifies an insulation fault, the location of the fault is often still unknown in the spatially extensive power supply system. To locate a faulty line outlet, a (branch) selective insulation fault location is therefore started after the insulation fault is detected. For this purpose, insulation fault location systems in accordance with the standard IEC 61557-9 are primarily used, which feed a test current into the power supply system centrally at the feed point; the spatial flow of this test current can be traced by measuring current transformers distributed throughout the power supply system to be monitored, as the test current closes the (insulation) fault location and is detected by all measuring current transformers located in the fault (test) circuit.

The measurement time or response time for identifying insulation faults in ungrounded power supply systems is significantly longer than 1 s (e.g., 5 s to 100 s), which means that so-called ground fault wipers, i.e., low-resistance insulation faults which appears momentarily intermittently, are not identified. In grounded power supply systems, e.g., in a TN network, residual current devices are used for rapid disconnection, which can also perform a disconnection or fault detection in the millisecond range. In this context, residual current devices are understood to be a generic term for protective devices which have a differential current sensor for detecting fault currents—these are primarily residual current protection devices (RCDs), modular residual current protection devices with external disconnecting devices (MRCDs), and residual current monitoring devices (RCMs).

Such residual current devices are only suitable to a limited extent for ungrounded power supply systems and, in particular, for ungrounded DC power supply systems, since in the event of a first fault, the fault current flowing is not large enough to achieve a selective disconnection or fault detection via differential current measurement.

Methods are known which, by appropriately adjusting the measurement times and the threshold values for certain network conditions, enable monitoring, provided that sufficiently large network leakage capacitances are available in the IT network. In some cases, artificial network leakage capacitances are also inserted to serve as a current return channel for the fault current and thus to trigger the residual current device for disconnection or an alarm notification. However, this method only works reliably in an ungrounded AC network (AC IT network), but not in an ungrounded DC network (DC IT network). In addition, artificially increasing the network leakage capacitance is counterproductive to the advantages of an IT system in terms of fire, personal, and equipment protection and impairs the functioning of the required insulation monitoring device.

The patent application document DE 10 2021 114 260 A1 describes an electrical circuit arrangement for standard-compliant insulation monitoring with rapid disconnection upon ground fault detection for an ungrounded power supply system. In this context, an IMD is coupled to the neutral point of an ungrounded power supply system, and a fault current is detected in the connection branch using an AC/DC sensitive differential current sensor (measuring current transformer). This is evaluated in an evaluation device so that the power supply system can be disconnected in the event of a fault using a separate switching device.

Patent application document DE 10 2021 127 848 A1 describes a method and a device for detecting and localizing cyclic short-term insulation faults in an ungrounded power supply system. To this end, various process variables, which indicate machine activity, for example, are correlated with a differential current measured by a differential current sensor.

However, the hitherto known solutions are only applicable under certain technical conditions—for example, sufficiently large network leakage capacitances must be present or an AC IT network must be available—and do not take into account the use of commercially available residual current devices such as RCDs, MRCDs, or RCMs.

### SUMMARY

The object of the invention is therefore based on being able to detect low-resistance insulation faults in an ungrounded DC power supply system—these low-resistance insulation faults appearing in short intervals—thereby enabling the use of commercially available residual current devices—which would otherwise not trip due to insufficient fault current—for the selective disconnection of line outputs.

This object is attained in relation to a device by a current return channel comprising an electronic circuit which is coupled between one of each of the active conductors and ground via two terminals and is configured to be automatically activated temporarily when a low-resistance insulation fault appears momentarily intermittently in order to form a fault circuit in which a current-limited fault current flows, which triggers the residual current device.

The underlying idea of the invention is to automatically provide a current return channel for a short but sufficiently long time interval when the insulation fault appears momentarily intermittently, thus forming a fault circuit in which a limited, yet sufficiently large fault current can flow, which is detected as a differential current by the differential current sensor of the residual current device and leads to its tripping. Depending on the type of residual current device (RCD, MRCD, RCM), tripping is understood in this context to mean both the triggering of an alarm notification and the execution of a switching function.

The current-limited current return channel thus enables the use of commercially available residual current devices—usually intended for installation in TN networks—in IT networks for selective ground fault wiper detection combined with selective disconnection of the line output affected by the insulation fault. At the same time, the advantageous properties of the ungrounded IT network are not permanently impaired.

The current return channel is implemented by an electronic circuit that is coupled bipolarly between each one of the active conductors and ground. The electronic circuit detects a low-resistance insulation fault appearing momentarily intermittently and then provides a purely electronically activatable current return channel between the respective active conductor and ground in order to close the fault circuit.

The electronic circuit according to the invention, which is simple in terms of circuit design and therefore robust (the electronic circuit does not have a microcontroller, for example) forms a safe, current-limited current return channel for a brief time interval.

In a further embodiment, the electronic circuit has a coupling branch which extends between the corresponding active conductors and ground, has a limiting resistor and a switching transistor switched in series to the limiting resistor the switching transistor being controlled via a trigger signal by an interlocking logic, the interlocking logic receiving detection signals from adaptive filters which detect and evaluate a displacement voltage at each active conductor to ground.

In the event of a ground fault wiper, there is a very significant change in the displacement voltage with a characteristic voltage curve between the active conductors and ground potential.

Adaptive filters detect the typical voltage shifts generated by the ground fault wiper and/or their characteristic voltage curves in a system-specific manner and forward this detection for each active conductor individually by means of detection signals to the interlocking logic for mutual interlocking of the complementary switching transistors. If one of the switching transistors is gated, the interlocking logic prevents the forwarding of possible trigger signals for controlling the respective complementary switching transistor.

The switching transistors each form the coupling branch which extends between the active conductors and ground and through which a sufficiently large fault current is now conducted. Limiting resistors in the respective coupling branch ensure the current limitation required for the ungrounded DC power supply system within the scope of the specifications.

Existing additional protective devices such as circuit breakers and insulation monitoring devices are not impaired in their function by this additional electronic circuit.

The current return channel according to the invention implements the method steps described in the independent method claim. In this respect, the aforementioned technical effects are also reflected in the method-related advantages of the claimed method according to the invention for the use of a residual current device with a differential current sensor in an ungrounded DC power supply system.

### BRIEF DESCRIPTION OF DRAWINGS

Further advantageous embodiment features are derived from the following description and the drawings, which describe a preferred embodiment of the invention in more detail using examples.

FIG. 1 shows an ungrounded DC power supply system.

FIG. 2 shows the ungrounded DC power supply system having line outputs and a current return channel according to the invention.

FIG. 3 shows the ungrounded DC power supply system having a current return channel according to the invention and disconnecting devices.

FIG. 4 shows an electronic circuit according to the invention as a current return channel.

FIG. 5 shows a temporal sequence in the event of a fault with activation of the current return channel and triggering of the residual current device as intended by the invention.

FIG. 6 shows the ungrounded DC power supply system with an activated current return channel according to the invention in the event of a fault.

### DETAILED DESCRIPTION

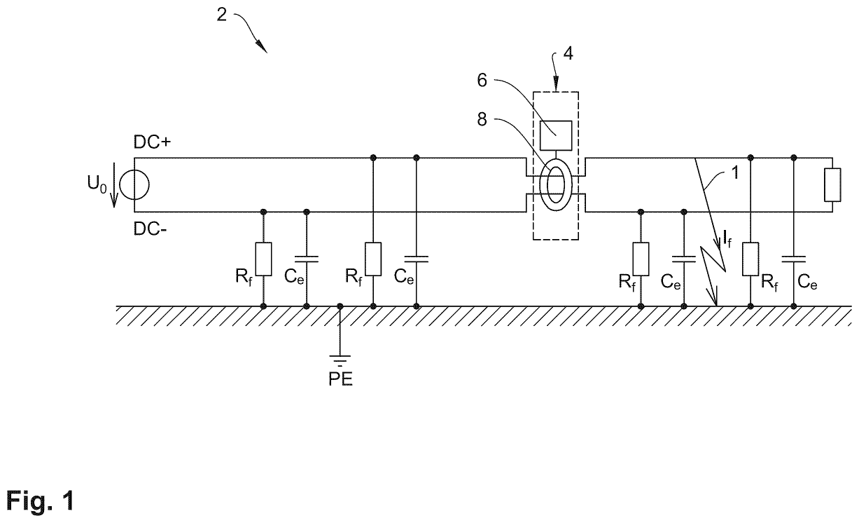

FIG. 1 shows an ungrounded DC power supply system 2 having active conductors DC+ and DC− and a voltage source U₀ to illustrate the problem. Between the active conductors DC+ and DC−, the ungrounded DC power supply system 2 has unavoidable leakage impedances relative to ground PE (ground potential), which manifest themselves as insulation resistances R_{f} and leakage capacitances Cₑ. For fault current monitoring, a residual current device 4, exemplarily designed as an RCM or MRCD, is installed as required in specifications and has a differential current evaluation unit 6 and a differential current sensor 8.

In the event of an insulation fault 1 in the form of a body or ground fault, a short-circuit current cannot flow as in grounded networks, but instead, due to the absence of a (resistance-free) return path, a fault current I_{f} will result, the magnitude of which is determined by the insulation resistances R_{f} and leakage capacitances Cₑ. In the ungrounded DC power supply system 2 (direct current network) underlying this, however, the leakage capacitances Cₑ prove to be ineffective in terms of their electrical conductance. Due to their very high resistance value in the fault-free case, the insulation resistances R only allow a very low fault current. However, this fault current I_{f} is not sufficient to trigger the residual current device 4.

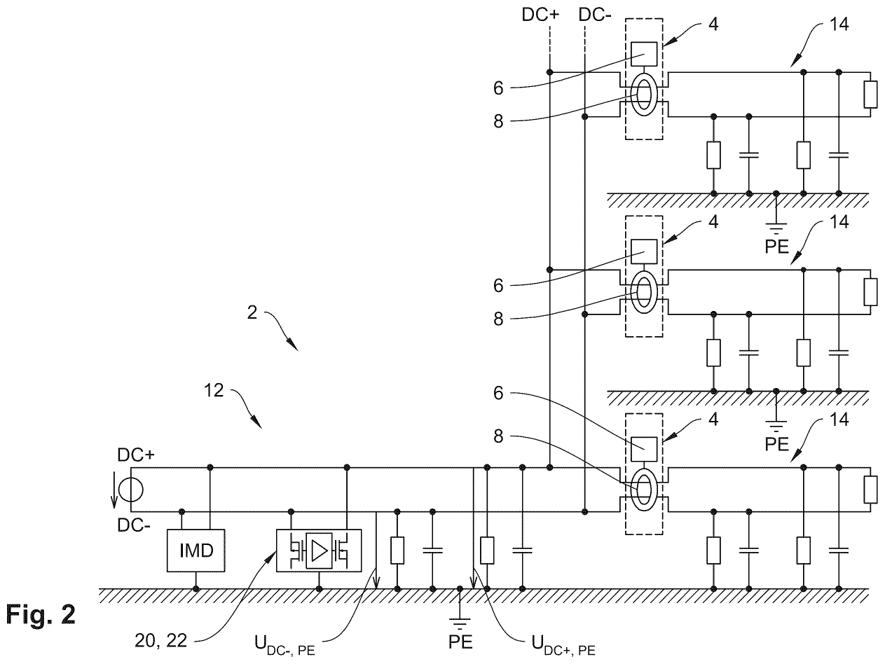

FIG. 2 shows the ungrounded DC power supply system 2 consisting of a main system 12 and line outputs 14 connected thereto. The line outputs 14 are monitored by the residual current device 4 for fault current detection by means of differential current measurement (differential current sensor 8).

A current return channel 20 according to the invention in the form of the electronic circuit 22 is coupled between one of each of the active conductors DC+, DC− and earth PE in the main system 12 via two terminals.

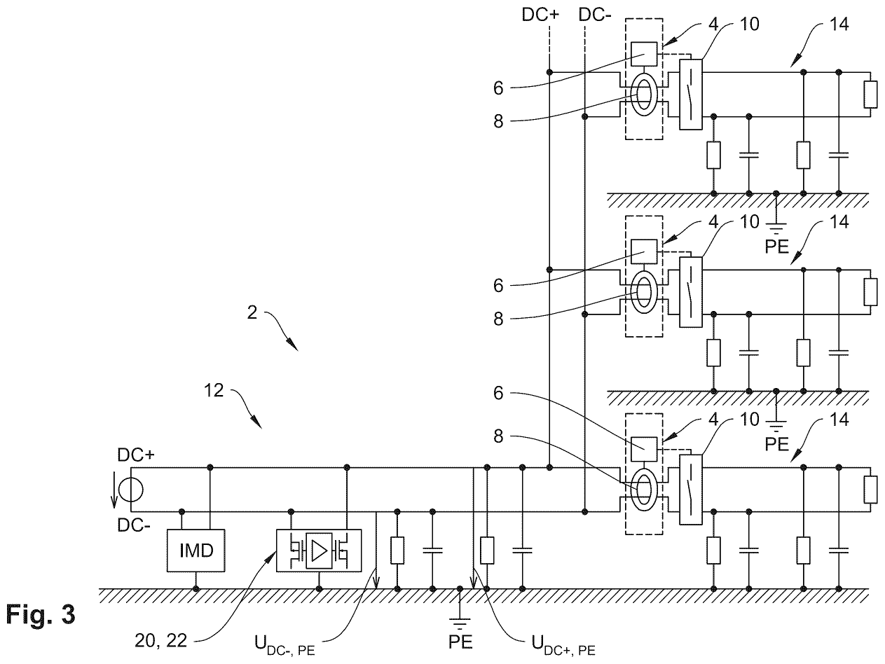

In FIG. 3, the residual current device 4, designed as an RCM or MRCD, has an external disconnecting device 10 which is directly connected to the differential current evaluation unit 6 of the RCM 4 or MRCD 4 and, as an external circuit breaker, can cause a branch-selective disconnection of a faulty line outlet 14. This enables selective rapid tripping. Alternatively, the switching function can be integrated into the residual current device 4 in the form of a residual current device (RCD).

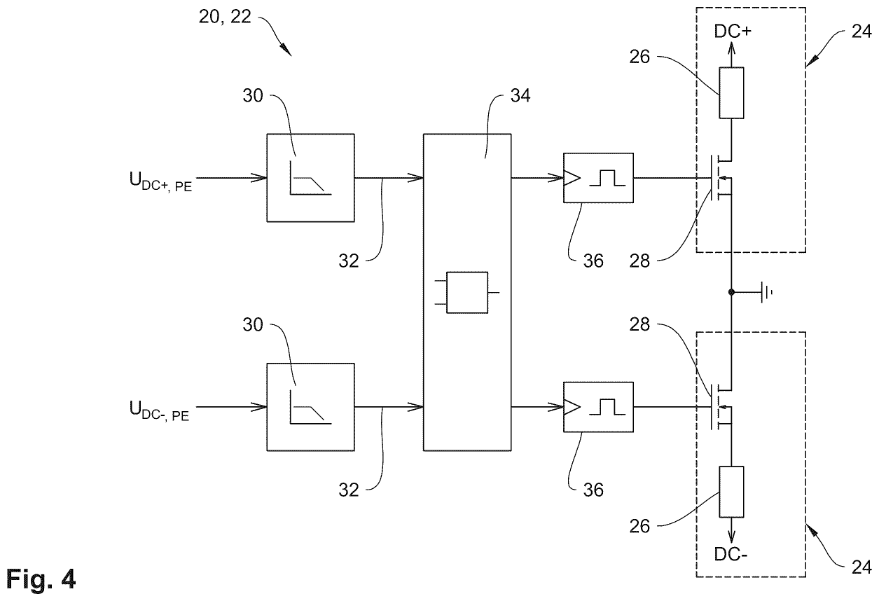

FIG. 4 shows an electronic circuit 22 according to the invention functioning as a reverse current channel 20 for the fault current I_{f} (FIG. 1).

The electronic circuit 22 has the task of detecting the course of the displacement voltages U_{DC+, PE}, U_{DC-, PE} between the active conductors DC+, DC− and earth PE, evaluating the detected course, and deriving the necessary switching actions for the switching transistors 28.

A necessary instruction for the electronic circuit 22 can be described as follows, for example:

Detect, using adaptive filters 30, the respective displacement voltage U_{DC+, PE}, U_{DC-, PE} on the active conductors DC+, DC− to ground (PE) and evaluate by comparison with threshold values, for example, whether the displacement voltages U_{DC+, PE}, U_{DC-, PE} are greater than 80% of the conductor-to-conductor voltage, or by correlating with voltage patterns, whether a displacement voltage curve characteristic of a low-resistance insulation fault 8 appearing at brief intervals (FIG. 1) is present.

Forward detection signals 32 from the adaptive filters 30 to an interlocking logic 34 if a voltage is exceeded or a characteristic curve of one of the displacement voltages U_{DC+, PE}, U_{DC-, PE} is detected.

Control the switching transistor 28 of the active conductor DC+, DC− affected by the insulation fault 8 by means of a trigger signal 36 from the interlocking logic 34 for a time interval, e.g., 50 ms, which is longer than the trigger time of the residual current device 4 used, while simultaneously interlocking the respective complementary switching transistor 28 via the interlocking logic 34.

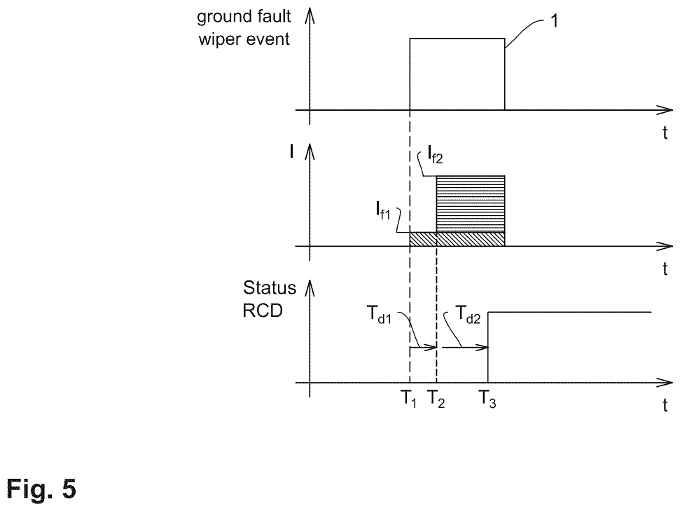

FIG. 5 shows a time sequence in the event of a fault (ground fault wiper event) with activation of the current return channel 20 and triggering of the residual current device 4 as intended the invention.

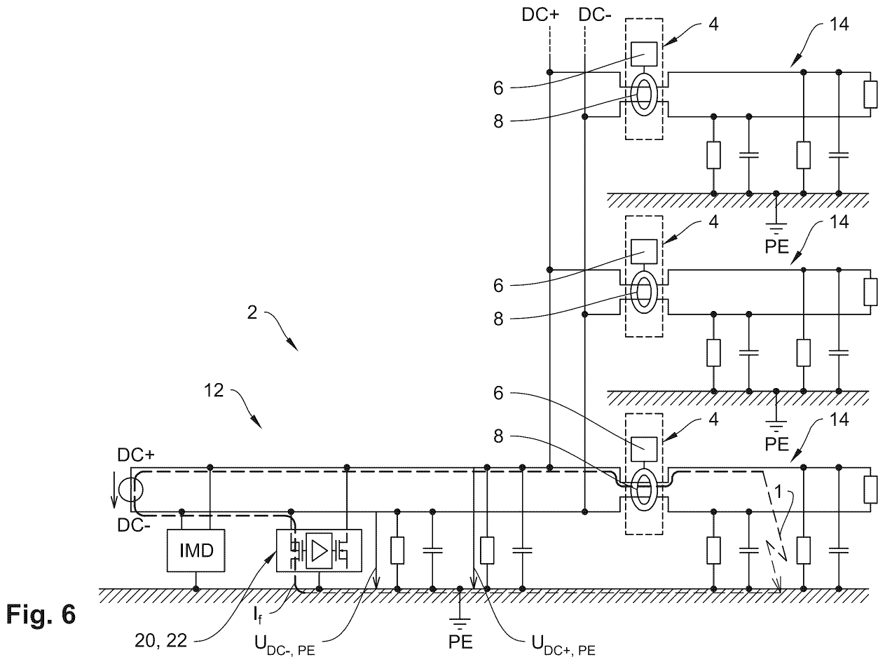

When a ground fault wiper event 1 occurs (see FIG. 1 and FIG. 6) at time T₁, a small fault current I_{f1} immediately begins to flow, the magnitude of which is caused and determined by the leakage impedance R_{f}, Cₑ of the network. After a certain reaction time T_{d1} of, for example, 1 ms, an increased fault current I_{f2} occurs at time T₂ due to the current component of the electronic circuit 22, so that the residual current device 4 can be triggered. The triggering occurs after a further reaction time T_{d2} at time T₃.

FIG. 6 shows the ungrounded DC power supply system 2 with the current return channel 20 activated according to the invention in the event of a fault (ground fault wiper event 1).

In the event of a ground fault wiper event 1 occurring in the line outlet 14, a fault circuit is formed via the electronic circuit 22 acting as a current return channel 20, a fault current I_{f} sufficiently large to trigger the residual current device 4 flowing in the fault circuit.

1. A current return channel (20) for the use of a residual current device (4) with a differential current sensor (8) in an ungrounded DC power supply system (2) having active conductors (DC+, DC−), the current return channel (20) consisting of an electronic circuit (22) which is coupled between one of each of the active conductors (DC+, DC−) and ground (PE) via two terminals and is configured to be automatically activated temporarily when a low-resistance insulation fault (1) appears momentarily intermittently in order to form a fault circuit in which a current-limited fault current (I_{f}) flows, which triggers the residual current device (4).

2. The current return channel (20) according to claim 1, wherein the electronic circuit (22) has a coupling branch (24) which extends between the corresponding active conductors (DC+, DC−) and ground, has a limiting resistor (26) and a switching transistor (28) switched in series to the limiting resistor, the switching transistor (28) being controlled via a trigger signal (36) by an interlocking logic (34), the interlocking logic (34) receiving detection signals (32) from adaptive filters (30) which detect and evaluate a displacement voltage (U_{DC+,PE}, U_{DC-, PE}) at each active conductor (DC+, DC−) to ground.

3. A method for the use of a residual current device (4) with a differential current sensor (8) in an ungrounded DC power supply system (2) having active conductors (DC+, DC−), the method comprising the step of automatically activating a current return channel (20) temporarily which consists of an electronic circuit (22) which is coupled between one of each of the active conductors (DC+, DC−) and ground via two terminals when a low-resistance insulation fault (1) appears momentarily intermittently in order to form a fault circuit in which a current-limited fault current (I_{f}) flows, which triggers the residual current device (4).

4. The method according to claim 3, characterized by detecting and evaluating a displacement voltage (U_{DC+,PE}, U_{DC-, PE}) at each of the active conductors (DC+, DC−) to ground (PE) by means of adaptive filters (30), forwarding detection signals (32) from the adaptive filters (30) to an interlocking logic (34), controlling a switching transistor (28) using trigger signals (36), the switching transistor (28) being disposed in series to a limiting resistor (26) in a coupling branch (24), which extends between the corresponding active conductor (DC+, DC−) and ground, and interlocking the corresponding complementary switching transistor (28) via the interlocking logic (34).
